(19) United States
(12) Patent Application Publication
(10) Pub. No.: US 2015/0212117 A1
(43) Pub. Date: Jul. 30, 2015

(54) MEASURING DEVICE FOR A CONTACTLESS CURRENT MEASUREMENT

(71) Applicants: RAUSCHERT HEINERSDORF-PRESSIG GMBH, Pressig (DE); FRAUNHOFER-GESELLSCHAFT ZUR FOERDERUNG DER ANGEWANDTEN FORSCHUNG E.V., Munich (DE)

(72) Inventors: Michael Hackner, Hemau (DE); Gerhard Tischlinger, Nuernberg (DE); Alfred Fiedler, Pressig (DE)

(21) Appl. No.: 14/419,632

(22) PCT Filed: Aug. 13, 2013
(86) PCT No.: PCT/EP2013/066868

§ 371 Date: Feb. 4, 2015

(30) Foreign Application Priority Data
Aug. 14, 2012 (DE) 20 2012 103 071.3

(51) Int. Cl. G01R 15/20

(52) U.S. Cl. CPC G01R 15/202

(57) ABSTRACT

A current measuring device for at least one contactless current measurement on an electric conductor. At least one magnetic field-sensitive magnetic field sensor with a corresponding electronic analyzing device is arranged in a housing having a first housing part and a second housing part connected to the first housing part via at least one pivot joint, and cut-out sections through which the insertable conductor passes provided in the end walls. The cut-out sections are shaped such that once one housing part is pivoted open relative to the other, the conductor can be inserted into the respective end-face cut-out section parts of the first housing part. Bearing shells are provided in the two housing parts, and a flexible conductor track carrier is inserted into the bearing shells, wherein the conductor track carrier receives the magnetic sensors of the measuring device.

The invention relates to a measuring device for at least one contactless current measurement at an electrical conductor which conducts current, with the features indicated in the preamble of claim 1.

A current measuring device of the kind in question is known from DE 20 2008 012 593 U1. The current measuring device indicated therein comprises a single-part or multi-part housing in which a sensor is arranged in the immediate vicinity of the current-conducting conductor to be measured. The measurement range, which is defined by the magnetic-field sensitivity of the sensor, of the conductor is surrounded by a screening chamber consisting of a screen of a non-magnetisable metallic material when the housing is closed. As sensor, use is made of a Hall sensor with polarity recognition, this being incorporated in a downstream amplifier circuit. The electrical evaluating device is similarly accommodated in the housing. Recesses of half-shell shape for reception of the conductor are formed in the side walls of the housing. The openable lid forms the other half of the recess and includes a part of the screen. In addition, a terminal to enable reading of measurement data out of the memory is provided in the housing at the lower side. The Hall sensor detects the magnetic field resulting from current flow through the conductor and thus delivers a proportional signal for the magnitude of the current flowing.

A measuring device for contactless current measurement at an electrical conductor conducting current is similarly known from 20 2007 005 947 U1, in which at least one Hall sensor is provided as current measuring sensor and is arranged with an appropriate evaluating device in a housing, which is at least partly surrounded by an electrically screening cover and which is fixable by means of a releasable holding device on an electrical conductor through which current flows. Further, an electrical plug connector accessible via a passage in a side wall is fastened to the circuitboard present in the housing. The measuring device is clamped onto a current conductor. In that case, the housing does not enclose the current conductor.

A measuring device for contactless current measurement of an electrical conductor through which current flows is known from U.S. Pat. No. 7,164,263 B2, in which a plurality of magnetic field sensors is arranged on a curved circuitboard. The circuitboard is arranged to extend radially in curved housing halves which in the closed state surround the conductor.

A current measuring device is also known from EP 2 541 261 A1, in which a housing upper part is mounted to be pivotable relative to the housing lower part and has a recess for reception of a current-conducting conductor. A magnetic film which partially surrounds the conductor when the two housing halves are pressed together is insertable into the pivotable housing half. Disposed below the conductor is the current sensor on a circuitboard, which is covered by the magnetic film.

A device for measuring electrical current, direct current and alternating current, which is imposed on the direct current, is known from DE 25 43 828 A1. This device consists of tongs with inductive coils, the jaws of which enclose a recess for the current-conducting conductor in the closed state.

Starting from the prior art defining the genre the invention has the object of designing the measuring device in such a way that the housing parts can be opened without hindrance so as to be able to push the housing in simple manner onto individual conductors of a cabled system and in a further refinement to make possible not only contactless current measurement, but also energy analysis and a flat elongated mode of construction of the housing.

The invention fulfils the object by design of the measuring device in accordance with the technical teaching given in claim 1. In order to make possible energy analysis, a voltage measurement is additionally provided in a further embodiment.

Advantageous developments of the invention are indicated in detail in the subclaims.

According to the invention it is provided in accordance with claim 1 that the first and second housing parts each have at the joint sides in the interior at least one respective substantially semi-cylindrical bearing shell, which shells substantially concentrically enclose the conductor when the housing is closed, that the bearing shells have a diameter which is such a size relative to the conductor that at least one flexible shape-matched conductor track carrier with at least one magnetic field sensor is insertable therein, the carrier having two curved sections which are connected together at the side facing the pivot bearing by way of a loop-shaped connecting section so mounted in the housing as to ensure or not obstruct at least the relative pivot movement of the housing parts during opening and closing of the housing, and that the section, which is placed in the first housing part, of the flexible conductor track carrier provided with conductor tracks is mechanically and electrically connected with a rigid or flexible circuitboard.

According to the invention, use can be made of, for example, a Hall sensor or a magnetoresistive sensor as magnetic field sensor. It has additionally proved that at least two Hall sensors lead to a satisfactory measurement result. The magnetic field sensors are so arranged on the flexible conductor track carrier that the magnetic field components are determinable by tangential measurement. For this purpose, they can be coated on the chip surface, for example of an ASIC, to extend parallelly and not—as usual with Hall sensors—vertically. Such Hall sensors are known from, for example, 20 2007 005 957 U1. Magnetoresistive sensors usable for magnetic field measurement are described in, for example, the periodical Automotive, issue of Aug. 7, 2004, pages 24 ff.

The construction has the advantage that the magnetic field sensor or sensors, which is or are preferably mounted on the inner side of the flexible conductor track carrier in the curved sections, which enclose the conductor, can be in direct contact with the conductor tracks. The electrical current in a conductor is detected by approximation of the ring integral of the magnetic flow density around the conductor. For that purpose, advantageously as magnetic field sensors a plurality of identical, highly integrated Hall sensor ASICs is coated on a flexible conductor track carrier. In that case the conductor track carrier does not have to be separated. The flexible conductor track carrier is wound around the conductor to form a closed curve. This can be carried out directly by the shell-shaped receptacles or, however, also by pre-shaping by means of inserts in the bearing shells. As a consequence of the mechanical construction, the arrangement of the magnetic field sensors on the flexible substrate and the capability of the sensors to be able to measure magnetic fields parallel to the chip surface the error with respect to approximation of the ring integral is negligible. It is possible with the magnetic field sensors to measure the magnetic flux density at equidistant points along an arcuate curve about the current-conducting conductor in a direction tangential to the notional integral gradient curve and this serves as a measure for the current. The Hall sensors in one embodiment are incorporated as magnetic field sensors in ASICs and offer the advantage that DC currents and not just alternating currents can also be measured. The measuring and evaluating methods are, as such, known.

The arrangement according to the invention ensures that installation of the flexible conductor track carrier in the plane is made possible and that thereafter through corresponding shaping or through pushing into the bearing shells the conductor is completely enclosed in desired manner by the two curved sections. The loop-shaped connecting member between the two sections ensures that the housing can always be opened, thus the upper housing part can be pivoted open relative to the lower to enable withdrawal of the lower housing part and the upper housing part from a conductor. The stated production advantages in installation and also in the introduction into the housing parts of a housing, are obvious.

The two housing parts are connected together at one side by way of one or more pivot joints or also by way of a hinge consisting of pivot joints, whilst at the other side a detent connection can be provided; however, a different lock securing means can also connect together the parts. It will be similarly obvious that the passages in the side walls, which consist of half shells, have to be of such a size that the conductor, which in diameter can be between, for example, 1 millimetre and 24 millimetres in size, can be inserted. In principle, uninsulated conductors can be inserted. However, it is also possible to insert conductors provided with an insulating layer, thus encased.

In order that the conditions of the German Association for Electrical, Electronic and Information Technologies, part 100, are adhered to and there is a sufficient contact spacing between the flexible conductor track carrier and the conductor tracks disposed thereon as well as of the components from the current-conducting conductor, a further embodiment provides that flat elements of insulating material with recessed portions enclosing the conductor are inserted into the housing parts between the conductor and the flexible conductor track carrier at least in the region of the bearing shells. It will be obvious that the loop-shaped connecting section is then placed above and below the flat elements, which lie one on the other, rearwardly in the recess of the two housing parts so as to enable opening of the two housing parts by pivotation about pivot joints present at the side walls.

In order to make possible even easier insertion of the conductor the pivot joint can also be realised by a simple assembly fixing, thus a solid unit of the two housing parts does not have to be produced by a static pivot joint. The housing parts can thus be connected together in such a way that the second housing part is displaceable relative to the first housing part, after being swung over, in height through a defined travel during closing, for which purpose interengaging guide elements and guides can be provided at the first and second housing parts. Thus, in an advantageous construction upwardly protruding, column-shaped guide elements can be provided, for example in the corner regions, at the lower housing part or at an insert, which receives all the components inserted therein, in the lower housing part, the guide elements slidably engaging in guide channels in the second housing part. Detent lugs, which engage with a detenting action over a detent edge in the guide in the second housing part, can be provided at the guide elements for fixing the unit. The guides are U-shaped channels adapted in shape to the cross-section of the column-like guide elements. The guide channel can have at the joint side of the housing part a chamfered entry which engages a locking front side during tilting of the housing part, in which the channel is present, relative to the guide element and at the same time makes possible an open inclined setting of the housing part. The pivot joint is thereby realised and can be used when the upper housing part is brought from the lower to the upper height position.

In principle, the bearing shells, mounts, support elements and the like can be accommodated in the housing of the lower housing part or formed integrally from plastics material. However, it is also possible to provide these parts and mountings at an insert which is made separately and also provided with the guide elements if these are present, which insert is then inserted in the housing part after installation. Such an insert can obviously also be provided in the upper housing part and connected with the lower housing part.

The conductor can consist of a plurality of wires and be of stranded construction, it can be flexible or, however, also provided as a current-conducting monofilament. The evaluating device is applied to a solid conductor track or a flexible conductor track carrier, which can form a unit with the flexible carrier for the magnetic field sensors and, for example, be mounted on an insulating plate. It can be an electrical amplifier, an ASIC carrying out the evaluation, and/or a programmed microprocessor. The data can be obtained by way of a fixed interface, for example a plug connector interface. The corresponding bushes or plug contacts are connected with the circuitboard and accessible by way of a recess in the housing or the plug connector protrudes into this recess, so as to be able to plug on the member complementary to the plug connector. However, the measurement data can also be filed in a memory which is a component of an RFID transponder, so that the measurement data can be read out by an RFID receiver and evaluated. Moreover, the measurement data can also be read out by remote technology if an appropriate coupling into the conductor is made.

It has proved particularly advantageous to let the bearing shells open at the rear side into chamber-shaped recesses or into a cavity in the housing parts, in which the loop-shaped connecting section can engage the flexible conductor track carrier, wherein the outer curved section of the connecting section lies near, at or on the pivot axis of the two housing parts. It will be evident that pivotation open and pivotation closed of the two housing parts about the hinge is thereby made possible without mechanical overloading of the loop-shaped connecting section occurring. This significantly increases the service life of such measuring devices even when these are subject to multiple use for line measurement of different conductors.

In a further embodiment it is provided that mounted on a rigid or flexible circuitboard is a further, flexible section or a prolongation, to which a measuring pin is fastened and contacted by a conductor track. The measuring pin is pressed by its point onto the conductor for the voltage measurement and, if insulation surrounds the conductor, this is penetrated, during closing of the housing, up to the conductor. This enables energy analysis, since in parallel with the current measurement the voltage is measured at the same time and thus the power is detectable and an energy analysis can be created therefrom. The included microprocessor has to be appropriately programmed in order to be able to carry out time-dependent evaluation of the measurement values for the energy analysis.

It will be apparent that the contacting of the measuring pin is equally possible with the conductor track on a flexible conductor track carrier, which, for example, is laid in the housing over a terminal tongue parallel to the flexible conductor track carrier for the magnetic field sensors. In principle, the bearing shells for reception of the flexible conductor track carrier for the magnetic field sensors can be mounted on one side. The measuring pin can be arranged between these and the housing wall. However, a spaced arrangement is also possible, in which the circuitboard on which the evaluating device is present is arranged between the two measuring points. This is within the discretion of the expert.

The bearing shells for the curved sections of the flexible conductor track carrier for the magnetic field sensors can be fixedly formed in the housing. However, they can also be realised by shaped parts—at least at one side—insertable into the housing. If these shaped parts are insertable, adaptation of the diameter of the passage to the diameter of the conductor or the cable can be carried out in simple manner by appropriate fitting, so that a smaller spacing between the conductor and the magnetic field sensor is given. Beyond that, the bearing shells can be of closed trough-shaped construction or, however, also defined only by lateral contours, so that the middle region of the curved section at which the magnetic field sensors are mounted is exposed, whilst the side parts rest on the half-shell surfaces or are held at these, as already indicated, by retaining means. The curved sections can also be glued to the half shells. In every case, the housing consisting of plastics material or ceramic can ensure by its shell-shaped receptacles that all parts are effectively insulated relative to one another. It is possible with one and the same housing to carry out, for example, current measurements of 240 V alternating voltage lines or direct current lines and also at lines conducting multiple KV voltages.

In order to be able to undertake adaptation of the measuring pin in simple manner in the case of different diameters it is provided in a further embodiment that the measuring pin is arranged in the first housing part in front of the passage in the side wall and is so supported against the force of a spring and/or engaged under by a setting element that the conductor after insertion into the housing can be pressed down by pressing-down means at least in the region of the measuring pin against this pin. It is ensured by the spring pressure that the measuring tip of the measuring pin, which consists of metal, penetrates the insulation layer and an adaptation to different diameters is possible within a defined range in simple manner.

In order to be able to basically undertake adaptation to different diameters of the current-conducting conductor the receptacles can be provided at the housing parts to be able to be clipped or plugged on, which receptacles can, for example, be plugged into recesses in the housing parts and have bearing shells for engaging over the conductor. It is possible through such a modular arrangement to not only design the bearing shells to be exchangeable, but also to change the conductor guidance in the measuring region of a measuring pin, also with respect to the passage in the side walls of the housing. The individual subassemblies are insertable into the housing or can be plugged onto the housing and form with the surface of the housing a closed unit.

In addition, the receptacles for the conductor can, for example, be constructed so that the measuring pin can pass through a wall. This receptacle can, as a receptacle shaped part, also at the same time, for example, form the pivot joint or a part of the pivot joint and is externally detented on the housing in corresponding recesses. The mating joint is then located on the second housing part and is connectible with the first in a simple manner, after meshing assembly, by connecting pins forming the pivot axis. These parts can also be constructed to be rotatable so that a lefthand/righthand opening is made possible, subject to the condition that the bearing shells for the flexible circuitboard are also arranged to be displaceable or are arranged to be rotatable through 180°. This also applies analogously to the circuitboard in the housing, so that a laterally offset arrangement is made possible. In addition, the housing can be vertically arranged to come into closing abutment not only on the left, but also on the right.

In order to make possible easier assembly of the flexible conductor track carrier, in a further embodiment shaped parts are laterally provided at the bearing shells, which parts are insertable into bearing recesses in the housing parts and have at least one recess adapted to the shape of the bearing shell, a groove or an edge for reception or support of at least the side strip, which protrudes beyond the bearing shell, of the flexible conductor track carrier. It will be apparent that, after insertion of the flexible conductor track carrier and through pressing in these shaped parts, shaping to the bearing shell takes place automatically by the edge engaging thereon and, in addition, a positional securing is given by corresponding interengaging projections and recesses. In a case of incised grooves a lateral attachment of the flexible conductor track carrier is possible.

Cutting free of the side walls of the bearing shell has proved to be an advantageous development of the receptacle for the conductor, since the side walls can thereby resiliently yield when, for example, a conductor which is somewhat thicker than the predetermined diameter is inserted. Such deviations can occur particularly when the conductor is surrounded by an insulating layer. The arrangement in the shaped part insertable into a recess of the housing part has the advantage that pivot joint elements can be mounted thereon so that a double function is achievable. The pivot joint elements consist, in known manner, of pivot bearing blocks which are arranged at a spacing from one another and between which an individual bearing block, which engages by lateral protrusions in mounting recesses of the lateral bearing block, is insertable. However, passage bores can also be provided and a bearing bolt or bearing pin inserted so as to enable pivot movement between two such parts. If, in addition, the parts are of symmetrical construction a hinge with the same components can be realised by simple 180° rotation and mounting on the two housing parts. Such shaped parts consist of plastics material and advantageously are clipped on. Elevations can be provided at the inner side of the bearing shell for centring of the inserted conductor.

The shape of the housing shall be constructed to be substantially polygonal at least in longitudinal direction in order, for example, to also be able to be mounted behind a current-conducting conductor extending parallel to a mounting wall. In the case of measurements in the milliampere range the influence of extraneous magnetic fields, inclusive of the earth's magnetic field, can be eliminated by covering the curved sections by a metallic layer of non-magnetic materials, such as is known from the specification DE 20 2008 012 593 U1 cited in the introduction. The housing can obviously also be constructed to be elongate and have curved end sections. However, any other form can also be realised. For insertable shaped parts, however, it is recommended to select an elongate, polygonal construction so that the same shaped parts are, through turning, usable not only in the upper housing part, but also in the lower housing part.

The invention is explained in more detail in the following by way of the embodiments illustrated in the drawings, in which:

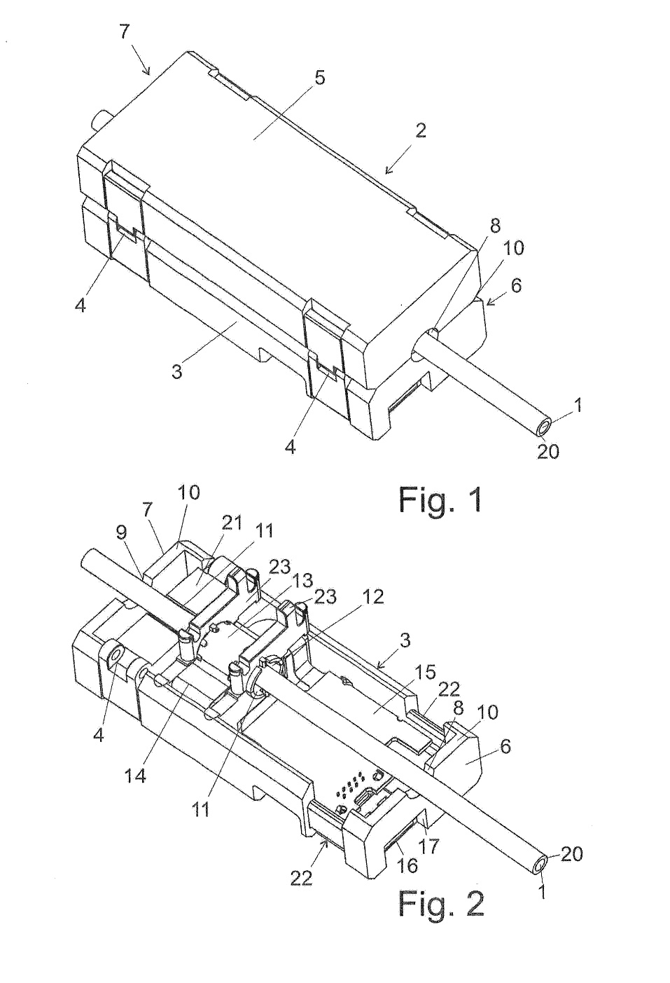

FIG. 1 shows, in an isometric illustration, a closed housing of a measuring device according to the invention with a conductor led through in longitudinal direction,

FIG. 2 shows, in an isometric plan view, the lower housing part of the housing according to FIG. 1 in opened state,

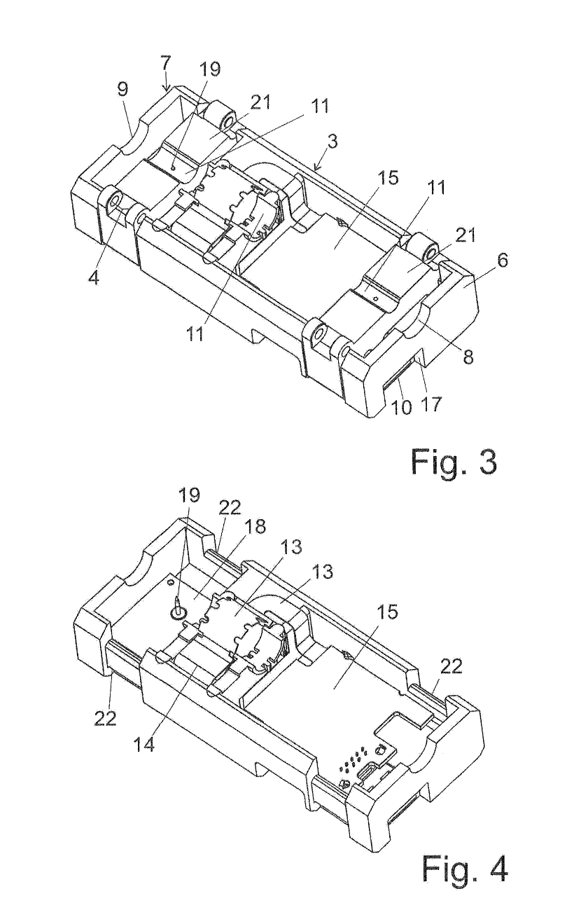

FIG. 3 shows the lower housing part according to FIG. 2 with removed conductor and inserted hinge-shaped parts with receptacles for the conductor,

FIG. 4 shows an isometric plan view of the lower housing part with removed hinge-shaped parts,

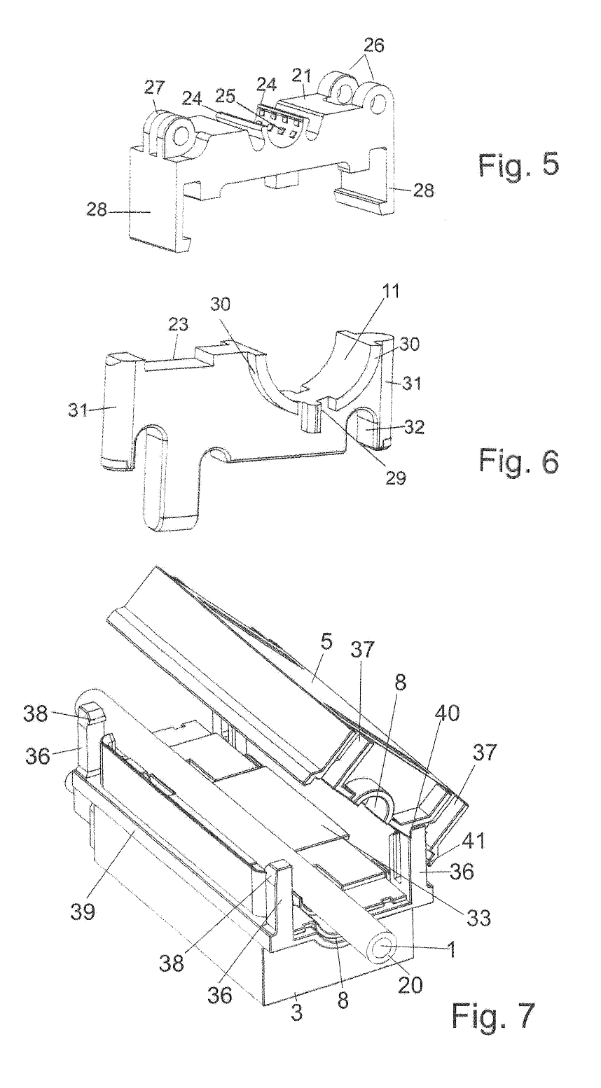

FIG. 5 shows an isometric illustrations of a shaped part with a bearing shell for the conductor and integrally formed pivot hinge elements as well as clip retainers,

FIG. 6 shows a shaped part which is insertable into the housing laterally of the bearing shell and enables easier mounting of the flexible conductor carrier and

FIG. 7 shows a further embodiment of a housing construction in an isometric illustration.

The embodiment illustrated in the figures shows a lower housing part 3 of a closed housing 2 and an upper housing part 5. The two housing parts 3 and 5 are connected together by way of two pivot joints 4 arranged in a row. These pivot joints 4 are of modular construction and externally detented in recesses 22 of the housing 2. As apparent from FIG. 3, each pivot joint module consists of a receptacle 21 with an inwardly disposed bearing shell 11, which extends in longitudinal direction and into which, as can be seen from FIG. 2, the conductor 1, which is surrounded by an insulating layer 20, is insertable. The two housing parts 3 and 5 form, in the closed state, end walls 6 and 7, which are penetrated by passages 8 and 9 effectively forming a round passage hole for the conductor 1 with the insulation 2. The housing 2 has a substantially elongate rectangular basic shape and is provided with recesses 22 so as to be able to receive the receptacles 21 provided with the joint parts of the pivot joints 4. These are clipped on from the outside and, in particular, not only in the first housing part 3, but also in the second housing part 5, so that the hinge parts interengage on the lefthand side and can be secured by a bolt (not illustrated), as apparent from FIG. 3. The corresponding receptacles 21 are fastened, turned through 180°, to the two housing parts 3 and 5 so as to enable meshing interengagement of the hinge parts of the pivot joints 4. In the closed state of the housing 2 the hinge which is formed can be used at other sides by a withdrawable pin as a lock. In addition, provided in the housing 2 is a mount on which a circuitboard 15 is fastened. Disposed on this circuitboard 15 are the contact tracks for the electronic circuit, as well as a plug connector 16, for example a USB interface, which protrudes out of a recess 17 in the housing end wall 6 and is accessible from the outside. By way of that the measurement values, which can be interrogated by the evaluating device (not illustrated), can be called up.

The flexible conductor track carrier 13, which is connected by way of a tongue-shaped transition part with the circuitboard 15 and can be pivoted open in transversely extending direction, is important to the invention. This conductor track carrier 13 receives the magnetic field sensors, for example Hall sensors, which are not illustrated and can be, for example, components of ASICs. The conductor track carrier 13 is so shaped that it has a lower curved section, which is insertable into a bearing shell 11 or into lateral bearing-shell-shaped receptacles and semicircularly engages under the conductor 1 at a spacing, whilst the upper end is embedded in the bearing shell 12 in the upper housing part 5 and forms the second arcuate part. Through the mounting of the conductor track carrier in the bearing shells 11 and 12 a complete enclosure of the conductor 1 together with the insulation in the closed state of the housing 2 is ensured.

In order that simple pivoting open of the housing part 3, 5 is possible the two curved sections of the conductor track carrier 13 are connected together by way of a connecting section 14, which is of loop-shaped form, or are constructed integrally therewith. This connecting section 14 lies in a chamber region or cavity region of the housing 2. The rear curved member is located close to the pivot axis, which is formed by the pivot joints 4, of the housing 2. It will be apparent that when the housing 2 is opened by pivotation of the upper housing part 5 relative to the lower housing part 3 about the rotary joint 4 the shaped parts 23, which are provided in the upper housing part 5 and have bearing shells 12 and which are insertable, are pivoted open therewith, whereby the upper curved section of the conductor track carrier 13 is pivoted open so that the conductor 1 can be inserted or removed or the housing 2 can be pulled off the conductor 1.

The shaped parts 23 are conceived as exchange parts so that different radii of the bearing shells 11 and 12 can also be realised. This is required if, for example, a conductor 1 with a larger diameter is to be inserted. The parts can be inserted in corresponding receptacles not only in that of the lower housing part 3, but also of the upper housing part 5.

It will be evident from FIGS. 3 and 4 that apart from current measurement by means of magnetic field sensors, the electrical voltage applied to the conductor 1 can also be measured. For this purpose a measuring pin 19 is provided at a prolongation 18 of the circuitboard 15 or at a flexible circuitboard, which is connected by way of a connecting part (not illustrated) with the circuitboard 15. The measuring pin 19 can be arranged to be displaceable against a spring. The spring pressure is in that case settable by means of a screw to ensure penetration through the insulation 20 so that the measuring pin can engage the conductor 1 when the conductor 1 is enclosed by the receptacles of the housing parts 2 and 3. It is thus possible to carry out not only contactless current measurement, but also a contact-linked voltage measurement, so that the evaluating circuit can also be used for the purpose of, for example, undertaking energy analysis and providing appropriate data, which can be carried out by way of a memory on the circuitboard 15. The memory can also be incorporated in an RFID transponder in order to be able to read out the transponder by way of an RFID reader if there are no possibilities of direct contact by way of, for example, a USB interface 16.

FIG. 5 shows a shaped part 21 in which the bearing shell is formed from side walls 24 cut free laterally. However, the wall thickness is selected in such a way that a spring effect is present so that adaptation to different external diameters of the conductor 1, particularly the insulation 20 thereof, is possible. Due to the fact that the side wall yields, an adaptation in height can also take place even when the housing is closed. In order to ensure centring of the conductor, elevations 25 are provided at the inner surface. The illustration additionally shows that the pivot joints 4 can be formed from pivot joint elements 26 and 27. In order to be able to respectively connect the shaped part 21 with the housing part 3 or 5, clip retainers 28 are provided which are insertable into correspondingly shaped recesses in the housing parts as apparent from FIG. 2.

The shaped part 23 is illustrated in enlarged form in FIG. 6. This shaped part can be introduced into the housing part 3, 5 to extend laterally at the bearing shells, for which purpose corresponding mounting recesses are provided in the housing parts 3, 5. In the embodiment, the shaped part 23 has laterally protruding edges 30, the lower curved surfaces of which correspond with the supporting base surface of the bearing shell 11 in the lower housing part 3 and 12 (not visible) in the upper housing part 5. It will be apparent that when the flexible conductor track carrier 13 is inserted then through insertion of the shaped part 23 a lateral locking and shaping of the conductor track carrier 13 on the shell 11 takes place automatically. The recesses, which are provided in the conductor track carrier 13 and which can co-operate with mounting points 29, for example securing protrusions, prevent displacement within the bearing shells 11, 12. An axial and a radial positional securing of the magnetic field sensors, which are present on the conductor track 13, is thereby given. The illustration additionally shows that the shaped part can have bearing sections, and also passages, for example for a sub-section of the conductor track carrier 13.

A further embodiment of a housing construction is illustrated in FIG. 7 in a perspective illustration, which differs from that in FIG. 1 essentially by the fact that the two housing parts 3 and 5 are, apart from the pivotable connection, also adjustable relative to one another in height position. For realisation there is inserted into the lower housing part 3 an insert 39 which has, in the corner regions, column-like guide elements 36 protruding upwardly out of the insertion plane. The four guide elements have detent lugs 38, the function of which will be explained later, at the upper end. Provided in the insert at the end are passages 8 which correspond with the shape of the inserted conductor 1 with the insulation 20. Also to be seen in the drawing is a flat element 33 which consists of plastics material and has a recessed portion corresponding with the shape of the conductor 1 with the surrounding insulation 20. This flat element 33 is paired with a guide element (not illustrated in FIG. 7) of such a kind that it can be laid in place so that the flexible circuitboard carriers (not illustrated) with the applied sensors and circuit elements are completely insulated from the conductor 1. The upper housing part 5 is depicted set at an inclination in the open setting. It will be apparent that the column-like guide elements 36 support, by the upper end surfaces, an inclined entry surface of the channel-shaped guide 37. A blocking flank 40, which engages the inner sides of the guide elements 36, prevents dropping out. In the illustrated inclined setting an abutment edge 41 at the side wall of the housing part 5 engages behind the guide element 36. This guide connection forms the pivot joint. If the housing part 5 is now tilted forwardly then the rear guide elements 36 slide into the guides 37. In that case the detent lugs 38 press against the inner slide surfaces of the guides. Equally, the front guide elements 36 are guided at the insert 39 in the front guides 37 so that the housing part 5 can be lowered in height relative to the lower housing part 3. In the end setting, the detent lugs 38 engage over the edges of the upper side of the upper housing part 5 and secure the connection. The rest of the construction otherwise corresponds with the embodiment according to FIG. 1.

### REFERENCE NUMERAL LIST

1 conductor
2 housing
3 first housing part
4 pivot joint
5 second housing part
6 end wall
7 end wall
8 passage
9 passage
10 abutment surface
11 bearing shell
12 bearing shell
13 conductor track carrier
14 connecting section
15 circuitboard
16 plug connector/USB interface
17 recess
18 prolongation
19 measuring pin
20 insulation
21 receptacle
22 recess
23 shaped part
24 undercut side wall
25 elevations
26 pivot joint element
27 pivot joint element
28 clip retainer
29 mounting point
30 edge
31 bearing section
32 passage
33 flat element
36 guide element
37 guide
38 detent lug
39 insert
40 blocking flank
41 abutment edge

1: A measuring device for at least one contactless current measurement at an electric conductor flowed through by current, wherein at least one magnetic field sensor sensitive to magnetic field is arranged as current measuring sensor with a corresponding electronic evaluating device in a housing, which comprises a first housing part and a second housing part connected therewith by way of at least one pivot joint, and passages for the passage of the insertable conductor are provided in the end walls and are so shaped that after pivotation open of one housing part relative to the other the conductor can be inserted into the respective end-face passage parts of the first housing part, wherein the first and second housing parts each have at the joint sides in the interior at least one respective substantially semi-cylindrical bearing shell, which shells substantially concentrically enclose the conductor when the housing is closed, that the bearing shells have a diameter which is of such a size relative to the conductor that at least one flexible shape-matched conductor track carrier with at least one magnetic field sensor is insertable therein, the carrier having two curved sections which are connected together at the side facing the pivot bearing by way of a loop-shaped connecting section so mounted in the housing as to ensure at least the relative pivot movement of the housing parts during opening and closing of the housing, and that the section, which is placed in the first housing part, of the flexible conductor track carrier provided with conductor tracks is mechanically and electrically connected with a rigid or flexible circuitboard.

2: The measuring device according to claim 1, wherein a plug connector, which is accessibly arranged in the first housing part via a passage in a housing wall, or a connector, which is inserted in a recess and electrically and mechanically connected with the rigid or flexible circuitboard, is provided, by way of which connector the measurement data can be called up by the evaluating device.

3: The measuring device according to claim 1, wherein the bearing shells open at the rear side into chamber-shaped recesses or a cavity in the housing parts, in which the loop-shaped connecting section engages the flexible conductor track carrier, wherein the outer curved section of the connecting section lies close to, on or in the region of the pivot axis of the two housing parts.

4: The measuring device according to claim 1, wherein mounted on the rigid or flexible circuitboard is a further, flexible section or a prolongation, by which at least one conductor is contacted by a measuring pin which, for voltage measurement, presses by its tip onto the conductor and, if insulation surrounds the conductor, penetrates this up to the conductor when the housing is closed, wherein the conductor is supported on the opposite side in a receptacle.

5: The measuring device according to claim 4, wherein the measuring pin is arranged in the first housing part in front of the passage in the end wall and is so supported against the force of a spring and/or engaged underneath by a setting element that the conductor after insertion into the housing can be pressed by a hold-down element at least in the region of the measuring pin against this pin.

6: The measuring device according to claim 1, wherein flat elements of insulating material with shaped portions enclosing the conductor are inserted in the housing parts between the conductor and the flexible conductor track carrier at least in the region of the bearing shells so as to ensure a defined contact state.

7: The measuring device according to claim 1, wherein the second housing part after being pivoted over is displaceable in height relative to the first housing part through a defined travel during closing, and interengaging guide elements and guides are provided at the first and second housing parts.

8: The measuring device according to claim 7, wherein the guide elements engage by detent lugs over locking edges at the guide elements when the housing is closed.

9: The measuring device according to claim 1, wherein provided in the first or the second housing part is an insert in which mounts and recessed portions are present in order to support the components and the conductor, which insert is connectible with the respective other housing part.

10: The measuring device according to claim 1, wherein for adaptation to the different diameters of the current-conducting conductor, with or without insulation, exchangeable receptacles, which are insertable into recesses in the housing parts and have bearing shells for engaging around the conductor, are provided at the housing parts to be able to be clipped or plugged on.

11: The measuring device according to claim 10, wherein when the housing is open the receptacles can be clipped on from the inner sides, wherein these receptacles have bearing shells made of plastics material and are mounted at least behind the current measuring arrangement and in the region of the measuring pin in front of or behind this.

12: The measuring device according to claim 1, wherein the two housing parts consist of plastics material or of ceramic material.

13: The measuring device according to claim 1, wherein the shape of the housing is constructed to be substantially elongate at least in longitudinal direction.

14: The measuring device according to claim 1, wherein apart from the evaluating device at least one RFID transponder with a memory in which the measurement values are stored so as to be able to be called up is mounted on the circuitboard.

15: The measuring device according to claim 1, wherein the curved section of the flexible conductor track carrier has in the edge region at least one recess or hole by which the flexible conductor track carrier is alignable with at least one mounting point.

16: The measuring device according to claim 1, wherein provided laterally at the bearing shells are shaped parts which are insertable into bearing recesses in the housing parts and which have at least one recess adapted to the shape of the bearing shell, a groove or an edge for reception or support at least of the side strip, which protrudes beyond the bearing shell, of the flexible conductor track carrier.

17: The measuring device according to claim 15, wherein the mounting points are provided at the bearing shells and/or at the shaped parts.

18: The measuring device according to claim 16, wherein the shaped part has a laterally protruding edge which can be engaged behind and which engages over the edge strips of the flexible conductor track carrier.

19: The measuring device according to claim 18, wherein recesses and knobs for positional securing of the magnetic field sensors and/or of the flexible conductor track carrier are provided in the region of the edge at the shaped part and/or in the edge and the flexible conductor track carrier has corresponding recessed portions.

20: The measuring device according to claim 10, wherein the bearing shells have undercut side walls and are of resilient construction.

21: The measuring device according to claim 20, wherein elevations for centering the inserted conductor are provided at the inner side of the bearing shell.

22: The measuring device according to claim 20, wherein pivot joint elements, which protrude at the shaped part externally in the corner region and which, by rotated arrangement, are connectible with mating elements protruding at the other housing part, are provided.

23: The measuring device according to claim 10, wherein lateral clip retainers are provided at the shaped part.

24: The measuring device according to claim 1, wherein the at least one magnetic field sensor is mounted at the inner side at a curved section of the flexible conductor track carrier or that a plurality of magnetic field sensors in uniformly oriented or in different angular settings with respect to the longitudinal axis of the conductor is provided at the inner sides of the curved sections.

25: The measuring device according to claim 1, wherein curved sections of the flexible conductor track carrier are externally surrounded by a screen of a non-magnetisable metallic material or such a material is coated on the surface.

26: The measuring device according to claim 1, wherein the magnetic field sensor is a Hall sensor or a magnetoresistive sensor.

27: The measuring device according to claim 1, wherein the magnetic field sensors are so arranged on flexible conductor track carriers that the magnetic field components are determinable by tangential measurement.
